(19) United States
(12) Patent Application Publication
(10) Pub. No.: US 2020/0327025 A1
(43) Pub. Date: Oct. 15, 2020

(54) METHODS, SYSTEMS, AND NON-TRANSITORY COMPUTER READABLE MEDIA FOR OPERATING A DATA STORAGE SYSTEM

(71) Applicant: ALIBABA GROUP HOLDING LIMITED, George Town (KY)

(72) Inventor: Shu LI, San Mateo, CA (US)

(21) Appl. No.: 16/808,146

(22) Filed: Mar. 3, 2020

Related U.S. Application Data
(60) Provisional application No. 62/831,883, filed on Apr. 10, 2019.

(51) Int. Cl. G06F 11/20; G06F 11/10; H03M 13/15; G06F 8/65

(52) U.S. Cl. CPC G06F 11/2094; G06F 8/65; H03M 13/154; G06F 11/1076

(57) ABSTRACT

The present disclosure provides methods, systems, and non-transitory computer readable media for operating a data storage system. The methods include receiving an I/O request to write a payload of data; encoding the payload of data, wherein the encoded data payload comprises a plurality of encoded data payload portions; selecting two or more secondary storage units from a plurality of secondary storage units coupled to the data storage system, wherein: the plurality of secondary storage units includes a first secondary storage unit that is being serviced, the first secondary storage unit, while being serviced, is not excluded from being selected as one of the two or more secondary storage units, and each of the encoded data payload portions are assigned to corresponding secondary storage units from the two or more secondary storage units; and sending the plurality of encoded data payload portions to the two or more selected secondary storage units for storage, wherein each encoded data payload portion is sent to the corresponding assigned secondary storage unit from the two or more selected secondary storage units.

### CROSS-REFERENCE TO RELATED APPLICATION

This disclosure claims the benefit of priority to U.S. Provisional Patent Application No. 62/831,883, filed on Apr. 10, 2019, which is incorporated herein by reference in its entirety.

### TECHNICAL FIELD

The present disclosure generally relates to data storage, and more particularly, to methods, systems, and non-transitory computer readable media operating a data storage system.

### BACKGROUND

Datacenters are an increasingly vital component of modern-day computer systems of all form factors as more and more applications and resources become cloud based. Datacenters provide numerous benefits by collocating large amounts of processing power and storage. However, because of their role in a large variety of contexts, constant uptime is a key concern for datacenters, who face severe repercussions for allowing data or resources to become inaccessible, such as from a firmware update. The need for constant uptime presents challenges, however, because secondary storage units, such as hard disk drives (HDDs) and solid-state drives (SSDs) routinely require updates, such as to patch bugs, enhance performance, or introduce new features. The current strategy of retaining I/O availability while upgrading a secondary storage unit utilizes secondary storage units with storage controllers with multiple cores that can be updated independently. However, the use of multiple storage controllers is problematic because it is expensive, causes a significant reduction in I/O performance, and leads to unpredictable switching which can be hard to control.

### SUMMARY OF THE DISCLOSURE

The present disclosure provides methods, systems, and non-transitory computer readable media for operating a data storage system. The methods include receiving an I/O request to write a payload of data; encoding the payload of data, wherein the encoded data payload comprises a plurality of encoded data payload portions; selecting two or more secondary storage units from a plurality of secondary storage units coupled to the data storage system, wherein: the plurality of secondary storage units includes a first secondary storage unit that is being serviced, the first secondary storage unit, while being serviced, is not excluded from being selected as one of the two or more secondary storage units, and each of the encoded data payload portions are assigned to corresponding secondary storage units from the two or more secondary storage units; and sending the plurality of encoded data payload portions to the two or more selected secondary storage units for storage, wherein each encoded data payload portion is sent to the corresponding assigned secondary storage unit from the two or more selected secondary storage units.

Additional objects and advantages of the disclosed embodiments will be set forth in part in the following description, and in part will be apparent from the description, or may be learned by practice of the embodiments. The objects and advantages of the disclosed embodiments may be realized and attained by the elements and combinations set forth in the claims.

It is to be understood that the foregoing general description and the following detailed description are exemplary and explanatory only, and are not restrictive of the invention, as claimed.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 is a schematic diagram illustrating a simplified overview of a data storage system, consistent with embodiments of the present disclosure.

FIG. 2 is a schematic diagram illustrates an example of a datacenter layout, consistent with embodiments of the present disclosure.

FIG. 3 is a schematic diagram illustrating an example layout of a storage cluster, consistent with embodiments of the present disclosure.

FIG. 4 is a schematic diagram illustrating an example multi-core secondary storage unit.

FIG. 5 is a diagram illustrating functionality of an example error correcting code, consistent with embodiments of the present disclosure.

FIG. 6 is a schematic diagram providing an example illustration of a data storage system responding to an I/O request to write a data payload while a secondary storage unit is offline for maintenance, consistent with embodiments of the present disclosure.

FIG. 7 is a is a flowchart outlining an example method of performing maintenance on a secondary storage unit while maintaining continuous servicing of I/O requests, consistent with embodiments of the present disclosure.

FIG. 8 is a schematic diagram providing an example illustration of how a secondary storage unit may be repaired with respect to a portion of an encoded data payload the secondary storage unit missed, consistent with embodiments of the present disclosure.

FIG. 9 is a flowchart outlining an example method of repairing a secondary storage unit with respect to a portion of an encoded data payload the secondary storage unit missed, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Modern day computers are based on the Von Neuman architecture. As such, broadly speaking, the main components of a modern-day computer can be conceptualized as two components: something to process data, called a processing unit, and something to store data, called a primary storage unit. The processing unit (e.g., CPU) fetches instructions to be executed and data to be used from the primary storage unit (e.g., RAM), performs the requested calculations, and writes the data back to the primary storage unit. Thus, data is both fetched from and written to the primary storage unit, in some cases after every instruction cycle. This means that the speed at which the processing unit can read from and write to the primary storage unit can be important to system performance. Should the speed be insufficient, moving data back and form becomes a bottleneck on system performance. This bottleneck is called the Von Neumann bottleneck. Thus, high speed and low latency are factors in choosing an appropriate technology to use in the primary storage unit.

Because of their importance, the technology used for a primary storage unit typically prioritizes high speed and low latency, such as the DRAM typically used in modern day systems that can transfer data at dozens of GB/s with latency of only a few nanoseconds. However, because primary storage prioritizes speed and latency, a tradeoff is that primary storage is usually volatile, meaning it does not store data permanently (e.g., primary storage loses data when the power is lost). Primary storage also usually has two other principle drawbacks: it usually has a low ratio of data per unit size and a high ratio price per unit of data.

Thus, in addition to having a processing unit and a primary storage unit, modern-day computers also have a secondary storage unit. The purpose of a secondary storage unit is to store a significant amount of data permanently. As such, secondary storage units prioritize high capacity—being able to store significant amounts of data—and non-volatility—able to retain data long-term. As a tradeoff, however, secondary storage units tend to be slower than primary storage units. Additionally, the storage capacity of secondary storage unit, like the metrics of many other electronic components, tends to double every two years, following a pattern of exponential growth.

However, even though secondary storage units prioritize storage capacity and even though the storage capacity of secondary storage units tends to double every two years, the amount of data needing storage has begun to outstrip the ability of individual secondary storage units to handle. In other words, the amount of data being produced (and needing to be stored) has increased faster than the storage capacity of secondary storage units. The phenomenon of the quickly increasing amount of data being produced is frequently referred to as “big data,” which has been referred to as a “data explosion.” The cause of this large increase in the amount of data being produced is largely from large increases in the number of electronic devices collecting and creating data. In particular, a large amount of small electronic devices—such as embedded sensors and wearables—and a large number of electronic devices embedded in previously “dumb” objects—such as Internet of Things (IoT) devices—now collect a vast amount of data. The large amount of data collected by these small electronic devices can be useful for a variety of applications, such as machine learning, and such datasets tend to be more beneficial as the amount of data the datasets contain increases. The usefulness of large datasets, and the increase in usefulness as the datasets grow larger, has led to a drive to create and collect increasingly large datasets. This, in turn, has led to a need for using numerous secondary storage units in concert to store, access, and manipulate the huge amount of data being created, since individual secondary storage units do not have the requisite storage capacity.

In general, there are two ways secondary storage units can be used in parallel to store a collection of data. The first and simplest method is to connect multiple secondary storage units to host device. In this first method, the host device manages the task of coordinating and distributing data across the multiple secondary storage units. In other words, the host device handles any additional complications necessary to coordinate data stored across several secondary storage units. Typically, the amount of computation or resources needed to be expended to coordinate among multiple secondary storage units increases as the number of secondary storage units being used increases. Consequently, as the number of attached secondary storage units increases, a system devotes an increasing amount of its resources to manage the attached secondary storage units. Thus, while having the host device manage coordination among the secondary storage units is usually adequate when the number of secondary storage units is few, greater amounts of secondary storage units cause a system's performance to substantially degrade.

Thus, large-scale computer systems that need to store larger amounts of data typically use the second method of using multiple secondary storage units in parallel. The second method uses dedicated, standalone electronic systems, known as data storage systems, to coordinate and distribute data across multiple secondary storage units. Typically, a data storage system possesses an embedded system, known as the data storage controller (e.g., one or more processor, one or more microprocessors, or even a full-fledged server), that handles the various tasks necessary to manage and utilize numerous attached secondary storage units in concert. Also comprising the data storage system is usually some form of primary memory (e.g., RAM) connected to the data storage controller which, among others uses, is usually used as one or more buffers. The data storage system also comprises one or more attached secondary storage units. The attached secondary storage units are what physically store the data for the data storage system. The data storage controller and secondary storage unit are usually coupled (e.g., connected) to one another via one or more internal buses. The data storage controller is also usually connected to one or more external host devices in some manner, usually through some type of I/O interface (e.g., USB, Thunderbolt, InfiniBand, Fibre Channel, SAS, SATA, or PCIe connections), through which the data storage controller receives incoming I/O request and sends outgoing I/O responses.

In operation, the data storage controller acts as the interface between incoming I/O requests and the secondary storage units. The data storage controller acts as an abstraction layer, usually presenting only a single unified drive to attached host devices, abstracting away the need to handle multiple secondary storage units. The data storage controller then transforms the incoming I/O requests as necessary to perform any I/O operations on the relevant secondary storage units. The data storage controller also performs the reverse operation, transforming any responses from the relevant secondary storage units (such as data retrieved in response to an I/O READ request) into an appropriate outgoing I/O response from the data storage system. Some of the transformation operations performed by the data storage controller include distributing data to maximize the performance and efficiency of the data storage system, load balancing, encoding and decoding the data, and segmenting and storing the data across the secondary storage units. Data storage systems—through the data storage controller—also are typically used to perform more complex operations across multiple secondary storage units, such as implementing RAID arrays.

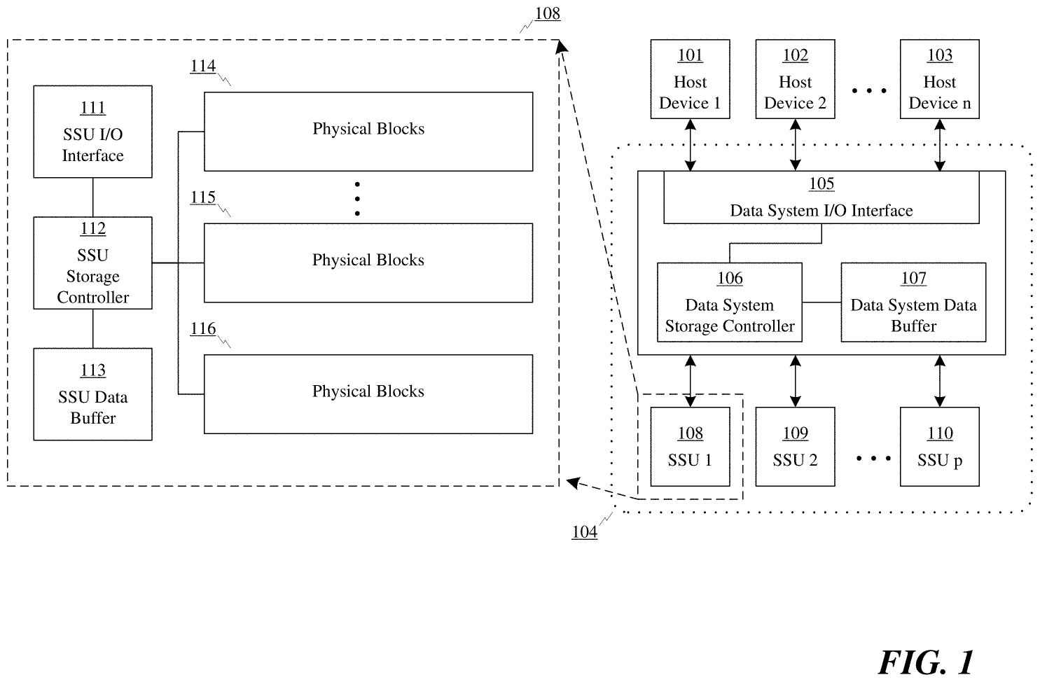

FIG. 1 is a schematic diagram illustrating a simplified overview of a data storage system. As shown by FIG. 1, data storage system 104 is composed of a data system storage controller 106, data system I/O interface 105, data system data buffer 107, and several secondary storage units (SSUs), shown here as secondary storage units 108, 109, and 110. Data system storage controller 106 receives incoming I/O requests from data system I/O interface 105, which data system storage controller 106 processes and, in conjunction with data system data buffer 107, writes data to or reads data from secondary storage units 108, 109, and 110 as necessary. The incoming I/O requests that data system storage controller 106 receives from data system I/O interface 105 come from the host devices connected to data storage system 104 (and which are thus using data storage system 104 to store data). As shown by FIG. 1, in general a data storage system may be connected to multiple host devices, shown here as host devices 101, 102, and 103.

Also shown by FIG. 1 is a basic schematic illustrating a generalized layout of a secondary storage unit. Using secondary storage unit 108 as an example. FIG. 1 shows how a secondary storage unit is composed of an SSU I/O interface 111 that receives incoming I/O requests and sends outgoing responses. SSU I/O interface 111 is coupled (e.g., connected) to SSU storage controller 112, which receives I/O request from SSU I/O interface 111. In conjunction with SSU data buffer 113, SSU storage controller 112 processes I/O requests by reading or writing data from physical blocks, shown here as physical blocks 114, 115, and 116. SSU storage controller 112 may also use SSU I/O interface 111 to send responses to I/O requests.

While data storage systems can appear even with traditional standalone PCs—such as in the form of external multi-bay enclosures or RAID arrays—by far their most prevalent usage is in large, complex computer systems. Specifically, data storage systems most often appear in datacenters, especially datacenters of cloud service providers (as opposed to datacenters of individual entities, which tend to be smaller). Datacenters typically require massive storage systems, necessitating usage of data storage systems. Typically, a data storage system used by a datacenter is a type of specialized server, known as storage servers or data storage servers. However, typically datacenters, especially the larger ones, have such massive storage requirements that they utilize specialized architecture, in addition to data storage systems, to handle the large volume of data.

Like most computer systems, datacenters utilize computers that are broadly based on the Von Neuman architecture, meaning they have a processing unit, primary storage unit, and secondary storage unit. However, in datacenters, the link between processing unit, primary storage unit, and secondary storage unit is unlike most typical machines. Rather than all three being tightly integrated, datacenters typically organize their servers into specialized groups called compute clusters and storage clusters. Compute clusters are composed of nodes called compute nodes, where each compute node is a server with (typically several) processing units (e.g., CPUs) and (typically large amounts of) primary storage units (e.g., RAM). The processing units and primary storage units of each compute node are tightly connected with a backplane, and the compute nodes of a compute cluster are also closely coupled with high-bandwidth interconnects, e.g., InfiniBand. However, unlike more typical computer systems, the compute nodes do not usually contain much, if any, secondary storage units. Rather, all secondary storage units are held by storage clusters.

Like compute clusters, storage clusters are composed of nodes called storage nodes, where each storage node is a server with several secondary storage units and a small number of processing units necessary to manage the secondary storage units. Essentially, each storage node is a data storage system. Thus, the secondary storage units and the data storage controller (e.g., the data storage controller's processing units) are tightly connected with a backplane, with storage nodes inside a storage cluster similarly closely connected with high-bandwidth interconnects.

The connection between compute clusters and storage clusters, however, is only loosely coupled. In this context, being loosely coupled means that the computer clusters and storage clusters are coupled to one another with (relatively) slower connections. While being loosely coupled may raise latency, the loose coupling enables a much more flexible and dynamic allocation of secondary storage units to processing units. This is beneficial for a variety of reasons, with one reason being that it allows dynamic load balancing of the storage utilization and bandwidth utilization of the various storage nodes. Being loosely coupled can also allow data to be split among multiple storage nodes (like how data within a storage node can be split among multiple secondary storage units), which can also serve to load-balance I/O requests and data storage.

Typically, the connection between secondary storage units and processing units is done on the basis of whole storage clusters communicating with whole compute clusters, rather than compute nodes communicating with storage nodes. The connection between storage clusters and compute clusters is accomplished by running all requests of a given cluster (computer or storage) through a load-balancer for the cluster. While routing requests through a load balancer on the basis of clusters raises latency, this arrangement enables large gains in efficiency since each system can better dynamically manage its traffic. In practice, compute time is typically the dominating factor, making memory latency relatively less of an issue. The large amount of RAM available also typically allows preloading needed data, helping to avoid needing to idle a compute node while waiting on data from a storage cluster.

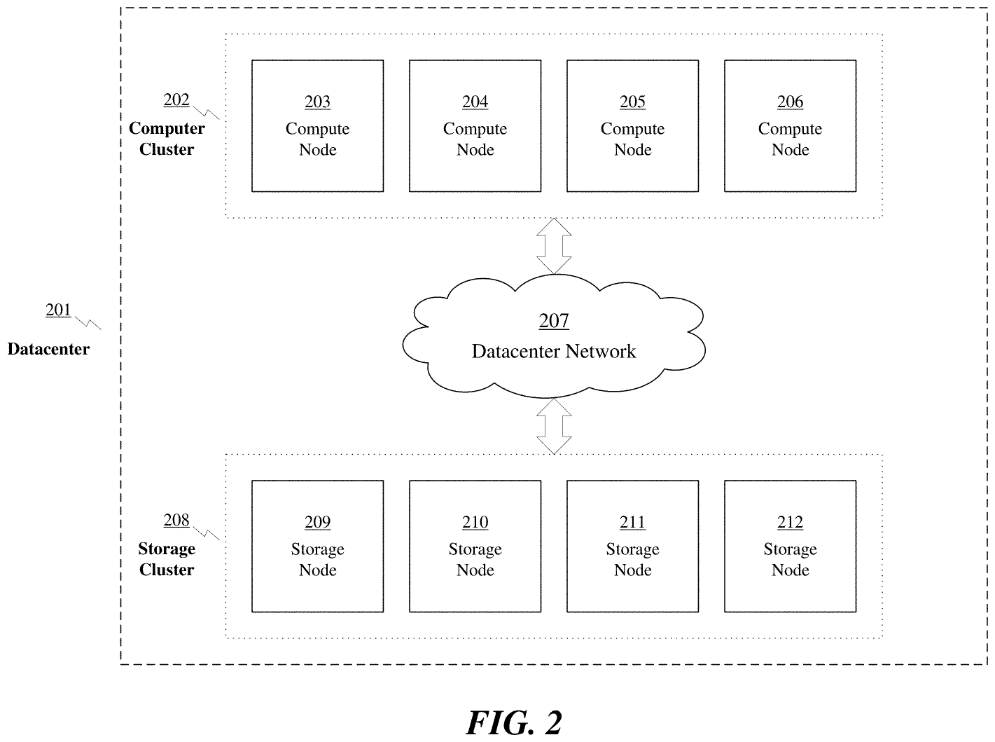

FIG. 2 is a schematic diagram illustrates an exemplary datacenter layout.

According to FIG. 2, datacenter 201 is composed of a computer cluster 202 and a storage cluster 208. Computer cluster 202 is composed of various compute nodes, here compute nodes 203, 204, 205, and 206. Similarly, storage cluster 208 is composed of storage nodes, storage nodes 209, 210, 211, and 212. Computer cluster 202 and storage cluster 208 are connected to each other via datacenter network 206. Not shown is the intra-cluster communication channels that couple compute nodes 203, 204, 205, and 206 to each other or the intra cluster communication channels that couple storage nodes 209, 210, 211, and 212 to each other. Note also that, in general, datacenter 201 may be composed of multiple computer clusters and storage clusters.

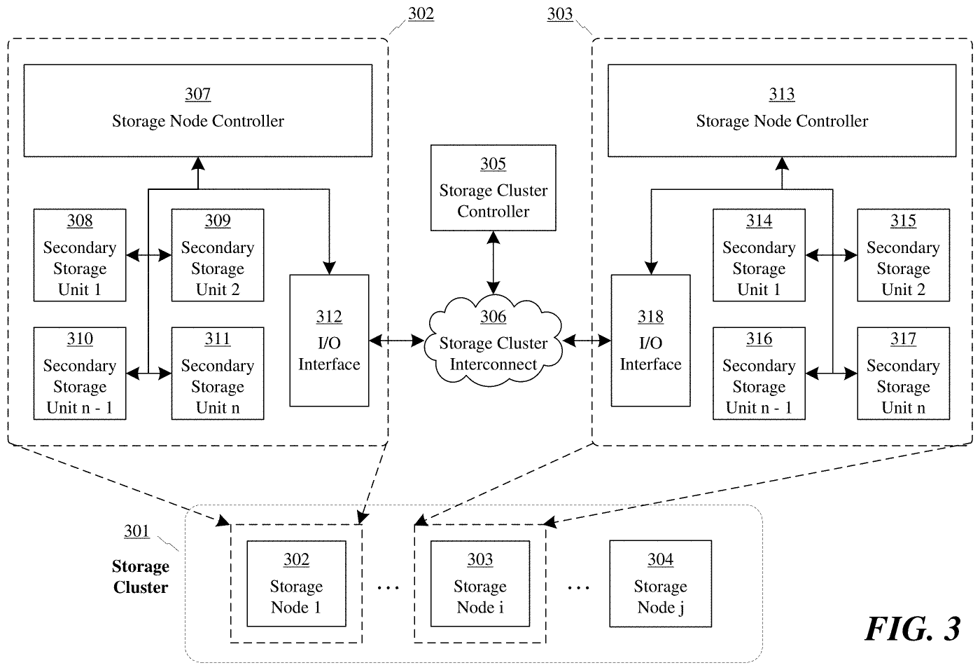

FIG. 3 is a schematic diagram illustrating an exemplary layout of a storage cluster. As shown by FIG. 3, storage cluster 301 is composed of various storage nodes, here shown as storage nodes 302, 303, and 304. By definition, each storage node is also a data storage system, though storage cluster 301 could also be considered a data storage system. Using storage node 302 as an example, FIG. 3 shows that each storage node is composed of a storage node controller 307, I/O interface 312, and several secondary storage units, shown here as secondary storage units 308, 309, 310, and 311. Storage node controller 307 receives I/O requests from I/O interface 312. Storage node controller 307 processes the received I/O requests and reads or writes data to or from secondary storage units 308, 309, 310, and 311 as necessary. The incoming I/O requests that storage node controller 307 receives from I/O interface 312 come storage cluster controller 305, which can communicate with the storage nodes in storage cluster 301 via the storage cluster interconnect 306. Also shown is the ability of storage nodes to communicate with one another via the storage cluster interconnect 306, shown here as storage node 302 and storage node 303 having a connection between one another.

However, while compute clusters tend to be the dominating factor, storage clusters are still essential to a datacenter's operation. A storage node typically is reading and writing data constantly. Thus, having data inaccessible for too long can degrade a datacenter's performance, as computer clusters waits for needed data from a storage node to become accessible. And aside from the technical issues, customers of datacenters typically expect constant uptime, with even small outages affecting customers' satisfaction and thus affecting a datacenter's profits. An outage can also affect a datacenter's profits because the outage may cause a breach in a service level agreement (SLA) the datacenter has with some of the affected customers. An SLA is an agreement between a datacenter and a customer that, among other things, specifies various minimum operating parameters the datacenter must meet. In particular, an SLA often stipulates monetary penalties if the datacenter fails to meet the minimum operating parameters. An example of one of the most common requirements of an SLA is “percentage uptime,” which is the percentage of time (e.g., 99.95%) a given resource (such as access to data stored in a cloud system) is guaranteed to be available, usually on a monthly basis.

Thus, the need for datacenters to maintain near constant data availability can be problematic, however, given that many secondary storage units—which are storing the data that must be available—need to be serviced at some point, which typically make the secondary storage unit unavailable for some amount of time. For example, one frequently occurring servicing needed by secondary storage units is installing/flashing a firmware upgrade. Since upgrading the firmware of a secondary storage unit involves modifying the code by which the secondary storage unit is running, upgrading a secondary storage unit's firmware typically means the secondary storage unit cannot respond to any I/O requests while it is upgrading. Other examples of servicing needed by secondary storage units include hot swapping a secondary storage unit with a replacement or rebuilding a RAID array (or other array of redundant data) with respect to the secondary storage unit. Another form of servicing needed by secondary storage units is various forms of maintenance, such as garbage collection or defragging. Host swapping and other forms of servicing typically means either a temporary loss of access to the data stored on the secondary storage unit (and thus temporary loss of some data stored on the data storage system) until the upgrade is complete, and may also result in loss of access to the data stored on the storage node/data storage system or a substantial reduction in I/O performance, particularly if the data storage system utilizes a RAID architecture.

While there have been some attempts to address the issues of servicing a secondary storage unit while maintaining data availability, they suffer from several limitations and drawbacks. In particular, the primary method used to address servicing a secondary storage unit without losing access to data stored on the secondary storage unit is to utilize secondary storage units which have storage controllers with more than one storage controller core. A storage controller core is the microprocessor inside a secondary storage unit that processes I/O requests. By utilizing multiple storage controller cores that can operate independently, a secondary storage unit can upgrade the firmware of one core (and then another) while still responding to I/O requests. However, this technique is only effective for maintaining data availability while upgrading a secondary storage unit's firmware; it is not effective for any other type of servicing a secondary storage unit might require. The use of multiple cores also comes with several drawbacks even for the limited domain of upgrading a secondary storage unit's firmware.

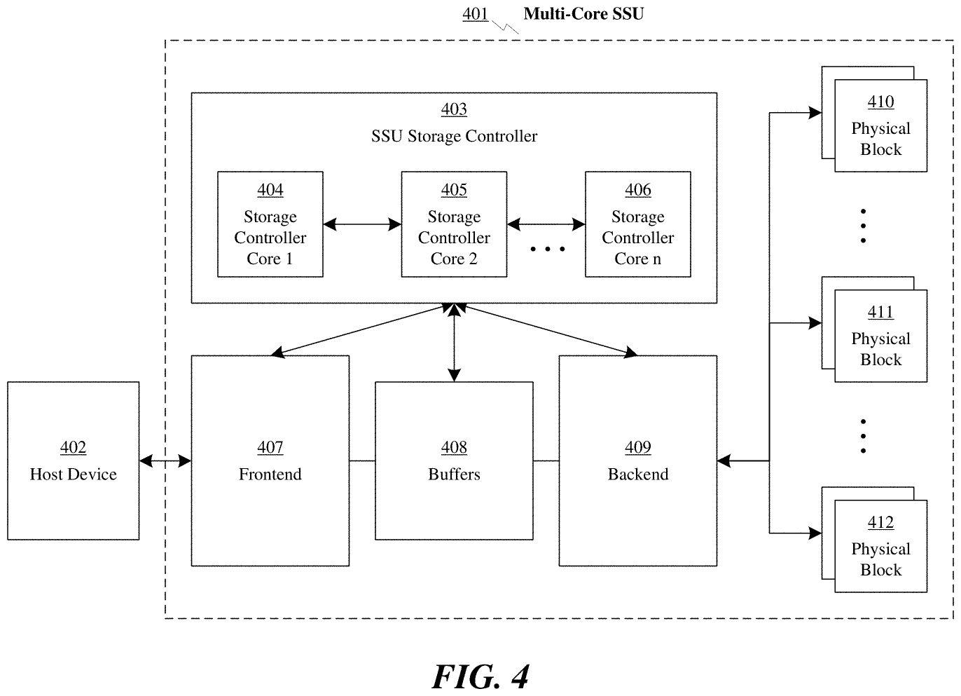

FIG. 4 is a schematic diagram illustrating an example multi-core secondary storage unit. According to FIG. 4, multi-core secondary storage unit (SSU) 401 is composed of a frontend 407 that receives incoming I/O requests from host device 402. SSU storage controller 403 receives the I/O requests from frontend 407, which is then processed by one of the cores in SSU storage controller 403, shown here as storage controller cores 404, 405, and 406. The selected storage controller core, in conjunction with buffers 408, processes the I/O request and, using backend 409, writes or reads data to or from physical blocks 410, 411, and 412 (which are the physical hardware physical storing the data) as necessary. Also shown by FIG. 4 is the connection between storage controller cores 404, 405, and 406, which facilitate handoff of I/O requests currently being processed by a storage controller core when the storage controller core begins the process of going offline to have its firmware updated.

As previously mentioned, using a secondary storage unit with a storage controller that has multiple cores is only effective for maintaining access to the data stored on the secondary storage unit with respect to firmware upgrades. Since other servicing tasks, such as replacing a defective secondary storage unit, might not allow access to the secondary storage unit at all, using multiple storage controller cores is ineffective. Another drawback of using multiple storage controller cores is that, while upgrading the secondary storage unit's firmware, the secondary storage unit's performance is degraded. The reason is that, typically, both storage controller cores are active and processing requests, thereby dividing the workload. When the secondary storage unit's firmware is being updated, however, one of the cores is selected to be updated, going offline. However, one storage controller core going offline leaves only the other storage controller core active and able to respond to requests, effectively halving the capacity of the secondary storage unit to handle incoming I/O requests in addition to the other management needs of the secondary storage unit. Additionally, the firmware upgrade process can take twice as long, since, when the updating storage controller core is finished updating, the updated storage controller core begins handling incoming I/O requests while the other storage controller core goes offline to be updated. The processing of taking a storage controller core offline, updating the storage controller core, bringing the updated storage controller core online, and then selecting another storage controller core lasts even longer in secondary storage units with more than two storage controller cores, increasing the amount of time the secondary storage unit's performance is reduced.

Additionally, a secondary storage unit with a storage controller containing multiple independent cores is more complex, increasing the cost of the secondary storage unit. The increased cost of a secondary storage unit with multiple independent storage controller cores can be especially important for datacenters, who use tens of thousands (or more) of secondary storage units, and thus can be especially sensitive to small cost increases. Also problematic is the hand-off of tasks between cores as one goes offline. The switching between storage controller cores is often unpredictable and hard to control, which can lead to irregularities, glitches, and increased latency as I/O requests must be handed off to the other cores.

Another method previously used to address some of the issues identified above is the use of RAID (Redundant Array of Independent Disks) to distribute data across multiple secondary storage units in a data storage system. RAID refers to a set of schemes for distributing data across multiple secondary storage units of a data storage system, indicated by a number, e.g., RAID 0. As is pertinent here, RAID 5 and RAID 6 involve encoding data using—one and two, respectively—parity based error correcting codes to provide data redundancy. The encoded data is then spread across multiple secondary storage units—at least three for RAID 5 and at least four for RAID 6—to allow recovery of data after the failure of one secondary storage unit—for RAID 5—or after the failure of two secondary storage units—for RAID 6. RAID does not define additional schemes allowing higher levels of data redundancy, e.g., the ability to recover data after the failure of three or more secondary storage units.

Like other previous methods, RAID suffers from several limitations. First, as just mentioned, RAID is restrictive, allowing only one (e.g., RAID 5) or two (e.g., RAID 6) secondary storage units to be offline at a time, with no ability to increase the number. Since only one or two secondary storage units may be offline while maintaining data availability, the probability of having a critical failure increases as the number of secondary storage units increases. Additionally, commercial RAID systems are restrictive in that they use only block-level data striping, with data encoded using only parity-based error correcting codes. The use of only block-level striping eliminates from consideration many error correcting codes based on other types of error correcting codes, such as convolutional codes.

Additionally, when a secondary storage unit in a RAID-based data storage system fails, the RAID array, while functional, has experienced a “fault.” To return the RAID array to full functionality (and data protection) the failed secondary storage unit is replaced with a new secondary storage unit which is then “repaired.” The process of repairing a secondary storage unit to return a RAID array to full functionality is called “rebuilding.” Rebuilding a RAID array typically involves reading the data present on the other secondary storage units to recalculate the data that belongs on the newly replaced secondary storage unit. Given that there can be an arbitrary number of secondary storage units, the time taken to rebuild a RAID array can take hours to days. Additionally, RAID suffers from what is known as write amplification, which can massively increase the amount of data that caused by a request for data to be written (or overwritten, which is especially problematic of SSDs), due to the need to recalculate and rewrite parity data. RAID-utilizing systems also have problems with parity inconsistency resulting from system crashes or other system anomalies.

To address these issues, some embodiments of the present disclosure utilize error correcting codes to enable one or more secondary storage units to undergo servicing, and thus be unavailable, without causing temporary loss of access to data or substantial degradation in I/O performance. By utilizing error correcting codes, some embodiments may distribute data across multiple secondary storage units in such a way that the loss of some number of secondary storage unit does not affect accessibility to any data stored on unavailable secondary storage units. Or, from the opposite perspective, utilizing error correcting codes ensures that any subset containing a threshold number of secondary storage units is sufficient to access any data stored on any of the secondary storage units. Allowing data to be accessible even with some secondary storage units offline simplifies the burden and complexity associated with upgrading secondary storage units using other methods and largely eliminates performance penalties due to the temporary loss of a secondary storage unit. The reduced complexity and elimination of performance penalties involved in upgrading a secondary storage unit reduces both the initial cost of secondary storage units and the cost of servicing them, particular for datacenters.

More specifically, error correcting code (ECC) works by encoding an original data payload into a longer, encoded data payload. The encoded data payload contains redundant data (the redundancy being precisely the difference in size between the original data payload and the encoded data payload). The presence of redundant data means that, should some part of the encoded data payload become lost or corrupted (up to a certain amount controlled by the amount of redundant information), the original data payload can still be recovered. A variety of methods and algorithms exist for how to encode the original data payload into an encoded form, with various characteristics, requirements, and performance results. As is pertinent here, error correcting code can be used to encode data being written to a data storage system. The encoded data can then be spread across multiple secondary storage units in such a way as to ensure that no single secondary storage unit (or a higher number, depending on the level of redundancy used) has more information than can be corrupted while still allowing the encoded data to be decoded into the original data.

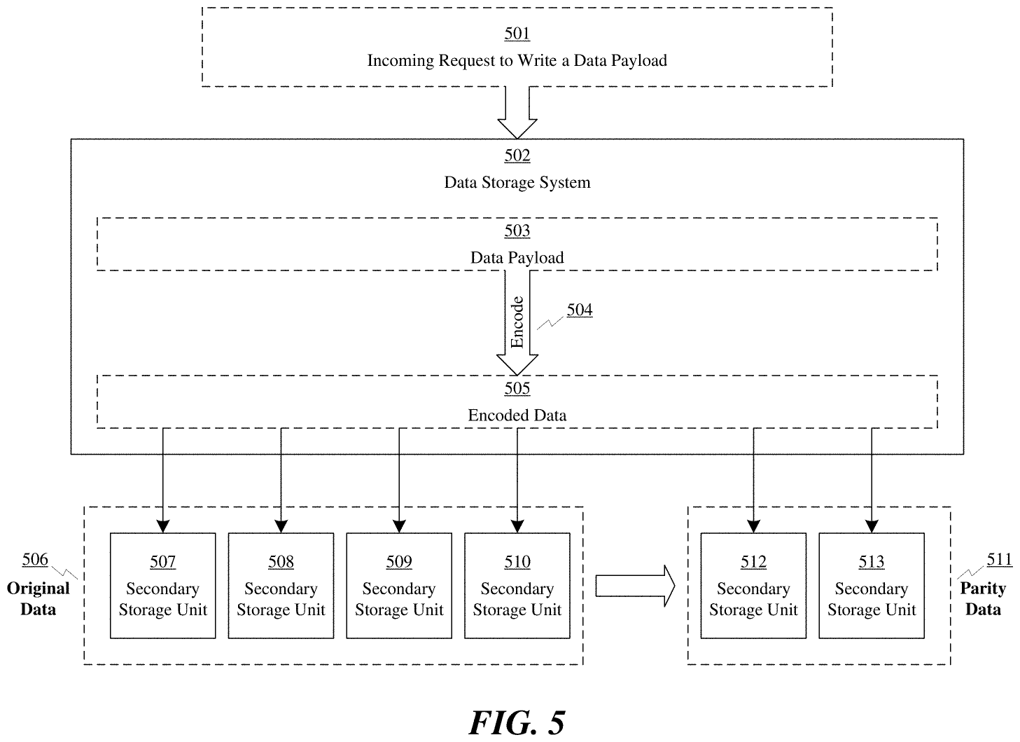

FIG. 5 is an exemplary diagram illustrating the functionality of an example error correcting code. According to FIG. 5, a request to write a data payload 501 may be received by a device, shown here as a data storage system 502. Data storage system 502 may take the data payload 503 and encode the data payload using a form of error correcting code 504. Encoding the data payload 503 results in encoded data 505, which is then stored on secondary storage units, shown here as secondary storage units 507, 508, 509, 510, 512, and 513. Specifically, FIG. 5 shows a form of error correcting code that is systematic, meaning that data payload 503 literally appears in the encoded data, shown by marker 506. The remainder parity data 511 is the redundant information, which is shown by marker 511.

Besides being useful to enable servicing of a secondary storage unit while maintaining data availability, as discussed in more detail below, error correcting code provides additional benefits. One such benefit is that data can be distributed across multiple secondary storage units in a redundant fashion to allow for faster effective bandwidth for reading data from a data storage system, since redundant distribution of data can allow data can be read from multiple secondary storage units in parallel. Another benefit of utilizing error correcting codes is that is the inherent data redundancy allows for continual access to data despite some number of secondary units being unavailable no matter the reason for the secondary storage units unavailability. Maintaining data availability even with the availability of some number of secondary storage units is of practical importance to datacenters, since, given their large size, secondary storage units are typically likely to fail. Maintaining data availability in the presence of the unavailability of some number of secondary storage units is beneficial more generally, since maintaining data availability allows data to be recovered. Maintaining data availability is also beneficial when servicing a secondary storage unit requires it to be taken offline or to become otherwise unavailable (e.g., unable to respond to I/O requests), since higher levels of redundancy can allow for unexpected failure of one or more secondary storage units as well.

One error correcting code particularly well suited for use in creating redundancy in data storage systems is erasure coding. Erasure coding works by taking a message of k symbols (such as a byte or group of bytes) and transforms them into n symbols, such that the original message can be recovered from some m number of symbols, k≤m≤n. The smaller the value m−k is, the more optimal the erasure coding used is said to be. The value of n−m, which is the number of symbols that can be lost while still allowing the message to be recovered, depends on the optimality of the erasure coding used and the number of excess symbols, i.e., the value of n−k.

Additionally, higher levels of redundancy in the data storage system, e.g., n−m≥2, can allow additional secondary storage units to be updated simultaneously. Thus for n−m=2, two secondary storage units could be simultaneously upgraded, for n−m=3, three secondary storage units could be upgraded simultaneously, etc. Higher levels of redundancy also allow for the possibility of a secondary storage unit failure (e.g., an unplanned loss of access to secondary storage unit), in addition to allowing for secondary storage units to be upgraded. As an example, n−m=2 can allow for one secondary storage unit to be upgraded while allowing for the failure of a single secondary storage unit. When n−m=3, it is possible to update one secondary storage unit while allowing for the failure of two secondary storage units or updating two secondary storage units simultaneously while allowing for the failure of one secondary storage unit. In general, where R=the number of secondary storage units being upgraded simultaneously and S=the number of secondary storage unit failures allowed for, R can be anywhere between 0≤R≤(n−m) and S can be anywhere between 0≤S≤(n−m)−R.

To utilize erasure coding to write data to a group of secondary storage units, the data is divided into groups of Drives_{Data} number of symbols, which are then encoded using erasure coding into Drives_{Total} number of codeword groups. One example is dividing the data into groups of Drives_{Data} number of bytes, then treating each byte as a symbol, which gives Drives_{Total} number of encoded symbols, called codewords. The codeword group for Driveᵢ is then just be the i-th codeword from each group of encoded symbols. Each codeword group can then be stored on different secondary storage units. To later recover and read the original data, exactly the reverse happens. Each codeword group is read from a secondary storage unit (or just each codeword group from Drives_{Data} number of secondary storage units is read), broken back into encoded byte groups, and then the encoded bytes are decoded using the reverse erasure coding operation to obtain the original data.

Specifically, to enable continuous access to data stored on a data storage system while servicing one or more of the attached secondary storage units, some embodiments of the present disclosure may determine that a secondary storage unit coupled (e.g., connected) to a data storage system needs servicing. For example, determining that a coupled secondary storage unit needs servicing may involve determining that a firmware update for one of the secondary storage units is available. As another example, determining a coupled secondary storage unit needs servicing may also involve determining that a secondary storage unit has failed, or is likely to fail soon, and thus may need to be replaced. Additionally, in some embodiments, determining a coupled secondary storage unit needs servicing may involve rebuilding data on a newly inserted secondary storage unit or having a secondary storage unit perform routine maintenance on itself, such as defragmentation or garbage collection.

After a secondary storage unit has been identified as needing servicing, some embodiments may then bring the identified secondary storage unit offline (e.g., marking the secondary storage unit as unavailable and no longer sending I/O requests to the secondary storage unit or otherwise acting as if the secondary storage unit available) while the secondary storage unit is serviced. Bringing a secondary storage unit offline may constitute, for example, internally marking the secondary storage unit as unavailable or not sending any I/O requests to the secondary storage unit. In some embodiments, bringing a secondary storage unit offline might also constitute unmounting the secondary storage unit, turning off power to the secondary storage unit, or physically disconnecting and removing the secondary storage unit.

After the identified secondary storage unit is brought offline, some embodiments may then continue to respond to incoming I/O requests, despite the selected secondary storage unit's—and thus the data stored on the secondary storage unit's—lack of availability. To continue responding to incoming I/O requests, in some embodiments it is first determined if the I/O request is a request to write a data payload (e.g., a WRITE request) or if the I/O request is a request to read a data payload (e.g., a READ request). The I/O request could also be something other than a WRITE request or a READ request, such as a TRIM command, which could be handled as normal or, if the I/O request needed the identified secondary storage unit to be available, queued until the identified secondary storage unit is again available. One example of an I/O request needing the identified secondary storage unit to be available is a TRIM command that involves data stored on the identified secondary storage unit.

If the I/O request is determined to be a request to write data, some embodiments may then proceed to encode the data payload using an error correcting code. The encoded data payload is then larger in size than the original data payload, containing additional, redundant information. To encode the data payload, some embodiments may utilize a general-purpose CPU, such as the storage controller core of a storage controller, to perform the encoding function on the data payload (or sequentially on portions of the data payload) to obtain the corresponding encoded form. Alternatively, some embodiments may utilize special hardware accelerators to perform the encoding operation. Some embodiments may employ both strategies and use both general-purpose CPUs and hardware accelerators to perform the encoding operation. Additionally, some embodiments may encode the entire data payload before proceeding to write or perform other operations with the encoded data. Some embodiments may encode the data payload in sections and begin storing the already encoded sections of the data payload while other sections of the data payload are still being encoded. Some of embodiments may employ both strategies; for example, some embodiments may wait for some data payloads to be entirely encoded before writing and for other data payloads may begin storing encoded sections of the data payload while other sections have not yet been encoded.

After the data payload has been encoded, some embodiments may then select two or more secondary storage units to store the encoded data payload on. For example, some embodiments may the secondary storage units based on current I/O activity of the plurality of secondary storage units, various characteristics of the plurality of secondary storage units, or even characteristics of the data payload. Some embodiments could select a secondary storage unit that has been brought offline and is being serviced, in which case the data intended for the offlined secondary storage unit may not be written until the secondary storage unit was brought back online. Before then, the data intended for the offline secondary storage unit could be temporarily written to another secondary storage unit, could be held in a buffer, or could be discarded and later re-derived from the encoded data stored on the other secondary storage units. Additionally, the secondary storage unit may be marked as needing to be repaired with regards the portion of the encoded data payload intended for the secondary storage unit. In any case, after the secondary storage units have been selected, some embodiments may then write the encoded data payload to the selected secondary storage units.

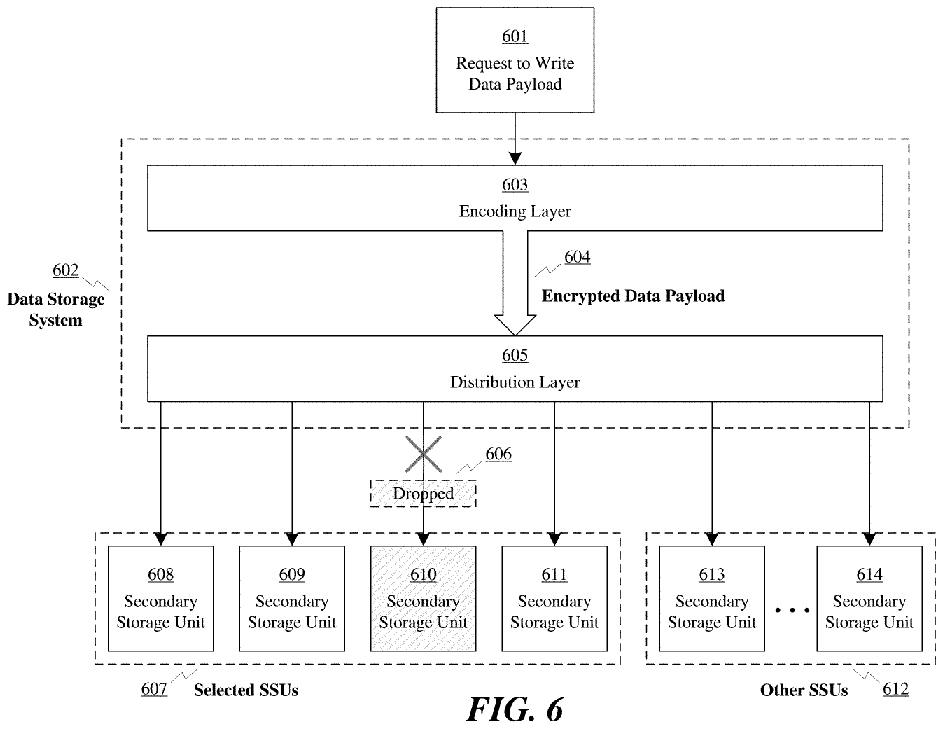

FIG. 6 is a schematic diagram providing an exemplary illustration of a data storage system responding to an I/O request to write a data payload while a secondary storage unit is offline for servicing. According to FIG. 6, a data storage system 602 may receive a request to write a data payload 601. In response to receiving the request to write data payload 601, data storage system 602 may, using its encoding layer 603, encode the data payload. The encoded data payload 604 is then sent to the distribution layer 605 of data storage system 602. Distribution layer 605 then selects a plurality of secondary storage units (SSUs) from the coupled (e.g., connected) secondary storage units, shown here as secondary storage units 608, 609, 610, 611, 613, and 614, to store the encoded data payload on. As shown here, distribution layer 605 selects secondary storage units 608, 609, 610, and 611. Among the selected secondary storage units 607 is a secondary storage unit 610 that is offline for servicing. As shown by FIG. 6, the portion 606 of the encoded data payload 604 that is intended secondary storage unit 610 may be dropped.

Alternatively, if the I/O request is determined to be a request to read a data payload, some embodiments may then proceed to read the encoded data corresponding to the requested data payload. Reading the encoded data may comprise, for example, consulting metadata indicating what encoded data or logical blocks correspond to the data payload and what secondary storage units the encoded data or logical blocks are located on. After it is determined what secondary storage units or logical blocks the data payload is located on, some embodiments may then read the encoded data payload—or its constituent parts—from the appropriate secondary storage units.

After the encode data payload has been read, some embodiments may then proceed to decode the data into the requested data payload (i.e., the original, unencoded data payload). To decode the data payload, some embodiments may utilize a CPU, such as the CPU core of a storage controller, to perform the decoding function on the data payload (or sequentially on portions of the data payload) to obtain the corresponding decoded form. Alternatively, some embodiments may utilize special hardware accelerators to perform the decoding operation. Some embodiments may employ both strategies and use both general-purpose CPUs and hardware accelerators to perform the decoding operation. Additionally, in some embodiments, the entire data payload may be decoded before proceeding to send or perform other operations with the decoded data payload. Some embodiments may decode the data payload in sections and begin performing operations with decoded sections of the data payload while other sections are still being decoded. Some embodiments may employ both strategies; for example, some embodiments may wait for some data payloads to be entirely decoded before sending and for other data payloads may begin sending or performing operations with the decoded sections of the data payload while other sections have not yet been decoded.

Finally, at some point the servicing of the secondary storage unit brought offline may be completed. Some embodiments may determine when the servicing of the secondary storage unit brought offline has been completed. After it is determined that the servicing of an offlined secondary storage unit has been completed, some embodiments may then bring the secondary storage unit online (e.g., marking the secondary storage unit as available and resuming sending I/O requests to it or otherwise resuming normal operations with the respect to it).

Bringing a secondary storage unit online may constitute, for example, internally marking the secondary storage unit as available or resuming sending any I/O requests to the secondary storage unit. As another example, bringing a secondary storage unit online might also constitute mounting the secondary storage unit, turning on power to the secondary storage unit, or physically connecting and attaching the secondary storage unit.

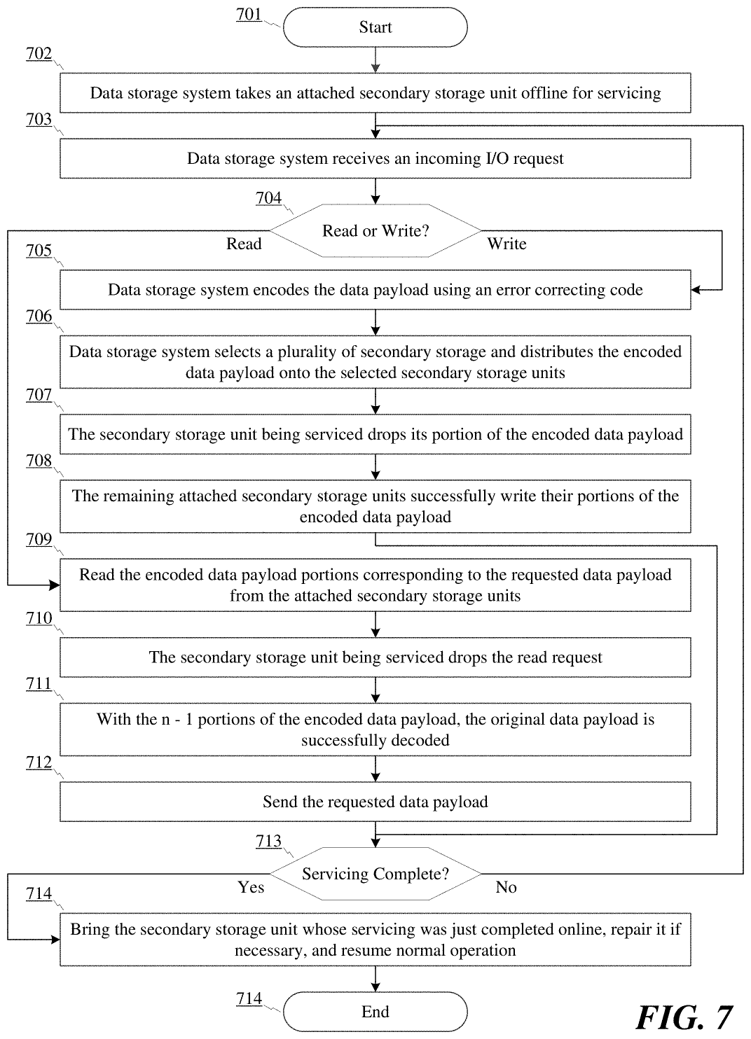

FIG. 7 is a flowchart outlining an exemplary method of servicing a secondary storage unit attached to a data storage system while continuing to respond to incoming I/O requests. The method may be performed by a data storage system (e.g., data storage system 502 of FIG. 5 or data storage system 602 of FIG. 6).

As show by FIG. 7, in the first step 702, a data storage system (e.g., data storage system 502 of FIG. 5) may take a secondary storage unit (e.g., secondary storage unit 509 of FIG. 5) offline for servicing. Next, in step 703, the data storage system (e.g., data storage system 502 of FIG. 5) may receive an I/O request (e.g., incoming request 501 of FIG. 5). In step 704, it is determined if the I/O request (e.g., incoming request 501 of FIG. 5) is a request to write a data payload or if the I/O request (e.g., incoming request 501 of FIG. 5) is a request to read a data payload. If the I/O request (e.g., incoming request 501 of FIG. 5) is a request to write a data payload, in step 705, the data storage system (e.g., data storage system 602 of FIG. 6) encodes the data payload using an error corrected code using the data storage system's encoding layer (e.g., encoding layer 603 of FIG. 6). Then, in step 706, the data storage system (e.g., data storage system 602 of FIG. 6) selects a plurality of secondary storage units (e.g., selected SSUs 607 of FIG. 6) and distributes the encoded data payload onto the selected secondary storage units using the data storage system's distribution layer (e.g., distribution layer 605 of FIG. 6). In step 707, if one of the selected secondary storage units (e.g., secondary storage unit 610 of FIG. 6) is being serviced, either the data storage system (e.g., data storage system 602 of FIG. 6) or the secondary storage unit drops (e.g., dropped encoded data payload portion 606 of FIG. 6) the offlined secondary storage unit's portion of the encoded data payload. In step 708, any secondary storage units not being serviced (e.g., selected SSUs 607 of FIG. 6 besides secondary storage unit 610 of FIG. 6) successfully write their portions of the encoded data payload.

Alternatively, if in step 704 it is determined that the I/O request (e.g., incoming request 501 of FIG. 5) is a request to read a data payload, in step 709 the data storage system (e.g., data storage system 502 of FIG. 5) reads the portions of the encoded data payload (e.g., portions of encoded data 505 of FIG. 5) corresponding to the requested data payload from the attached secondary storage units (e.g., secondary storage units 507, 508, 509, and 510 of FIG. 5). If one of the attached secondary storage units is being serviced, in step 710 the secondary storage unit being serviced drops (e.g., does not respond to the I/O request to read) its portion of the encoded data payload. Next, in step 711, the data storage system (e.g., data storage system 502 of FIG. 5) decodes the portions of the encoded data payload that are successfully read into the original data payload (e.g., data payload 503 of FIG. 5). In step 712, the data payload is then sent in response to the I/O request (e.g., incoming request 501 of FIG. 5).

After step 708 or step 712, it is determined if the servicing of the secondary storage unit being serviced has been completed at step 713. If servicing of the offlined secondary storage unit has not been completed, the method repeats at step 703. If servicing of the secondary storage unit has been completed, in step 714 the secondary storage unit is brought back online, repaired if needed, and made to resume normal operation.

The data storage system may be any one of the numerous types of electronic systems. For example, in various embodiments the data storage system could be a server, a storage node or storage cluster in a datacenter, a desktop computer, a laptop computer, a disk array, a RAID array, a server farm, a tablet, a smartphone, a wearable device such as a smartwatch, an embedded device, an orbital satellite, or any other von-Neuman-architected computer possessing a secondary storage unit.

How the secondary storage units are coupled (e.g., connected) to a data storage system may vary between embodiments. For example, in some embodiments one of more of the coupled secondary storage units may be physically attached to the device, such as through a USB, Thunderbolt, InfiniBand, Fibre Channel, SAS, or SATA connections. Additionally, in some embodiments, one or more of the coupled secondary storage units may not be physically attached to the device but instead are networked, meaning that the secondary storage units are accessible over the device's network connection. Examples include SANs, NASs, cloud storage, and using other device's as remote targets. Some embodiments may have accessible secondary storage units that are of both types, e.g., some secondary storage units may be physically attached, and some secondary storage units may be networked.

When selecting one or more secondary storage units, including the number and identity of the selected secondary storage units, some embodiments may make the determination based on various criteria. Some embodiments may make the determination based on characteristics of the secondary storage units, such as the type of secondary storage unit (e.g., HDD vs. SSD), current or historical I/O utilization of the secondary storage unit, performance characteristics such as READ or WRITE speed of the secondary storage unit, or capacity utilization of the secondary storage unit. The criteria may also consider characteristics of the data being stored, such as if the data is frequently or infrequently accessed. The rationale being that data that is more frequently accessed should be stored on faster, more powerful, better secondary storage units for performance reasons, and vice-versa.

Some embodiments may also consider characteristics of the data payload, when selecting secondary storage units to write the data payload too. For example, some embodiments may consider if the data payload, or a portion of the data payload, is frequently written. One way the information about the frequency a data payload is written may be used is to ensure that information more frequently written is stored on a faster secondary storage unit. Doing so could increase the effective speed of the data storage system, increasing the data storage system's apparent performance to its attached system and to end users. Some embodiments may also consider characteristics of the data payload to determine the characteristics of any write requests. For example, data that is written to in small, random fragments could be stored on a faster secondary storage unit better able to handle such small write requests. As another example, some embodiments may consider how often a data payload is read compared to how often the data payload is written.

Some embodiments may also select secondary storage units on a different basis than for every data payload. For example, some embodiments may select to store the next x number of data payloads on the selected secondary storage units. As another example, some embodiments may choose to store all data payloads received with a certain timeframe on the selected secondary storage units. Also, some embodiments may choose to store all data payloads up to a certain amount of data on the selected secondary storage units. Some embodiments may use a combination of criteria to select a secondary storage unit, such as next x number of data payloads received within a certain time and up to a maximum amount of data.

Some embodiment may use various types of error correcting code. For example, some embodiments may encode the data payload using erasure codes. Examples of erasure codes some embodiments may use include tornado codes, low-density parity-check codes, fountain codes, online codes, LT codes, raptor codes, parity codes, parchive, Tahoe-LAFS, or Reed-Solomon codes. Some embodiments may also utilize various types of block codes to encode the data payload (and generate redundant data). Additionally, some embodiments may use various types of convolution codes to encode the data payload. Some embodiments may also employ multiple different types of error correcting codes. Some of the embodiments employing multiple different types of error correcting codes may choose which error correcting codes to employ on varies criteria, such the type of data payload, how the data is accessed, the secondary storage units available, the secondary storage units selected, the processing time predicted to be taken to encode the data payload, the processing time historically taken to encode a data payload, the number of secondary storage units being used, or the characteristics of the secondary storage units being used.

If more than one secondary storage unit needs servicing, some embodiments may select more than one secondary storage unit to be taken offline. When selecting only a subset of a group of secondary storage units that all need to be serviced, different criteria may be used. For example, some embodiments may select one or more secondary storage units based on the form of error correcting code used to encode the data, since the form of error correcting code used usually determines the maximum amount of secondary storage units that can be offline simultaneously. Some embodiments may also choose which secondary storage units to take offline based of criteria such as current or historical I/O activity of the secondary storage units, the relative importance or predicted need for the secondary storage units, the type of servicing needed, or the urgency of the servicing needed (e.g., replacing a secondary storage unit that has failed may be a higher priority than updating the firmware of a different secondary storage unit).

What constitutes a need for servicing may vary for different embodiments. For example, in some embodiments a need for servicing may include the release of newer firmware for the secondary storage unit, failure of the secondary storage unit, predicted failure of the secondary storage unit, the need to rebuild the data on the secondary storage unit, or the need for background tasks by the secondary storage unit, such as defragmentation or garbage collection.

Additionally, various embodiments may determine whether a secondary storage unit needs servicing through a variety of mechanisms. For example, in the case of a firmware update, the determination could be made by checking the manufacturers website hosting the latest firmware and comparing the date the firmware was released with the date the secondary storage unit's firmware was last updated. Similarly, the determination could be made by checking the manufacturer's website and comparing version of the firmware with the version number of the firmware of the secondary storage unit. A data storage system may also receive a notification that a new firmware update is available.

Some embodiments may also use other mechanisms to determine when a secondary storage unit needs servicing. For example, in the case of rebuilding the data on the secondary storage unit, the determination may be made by ascertaining if the secondary storage unit dropped any portion of the encoded data payload (e.g., codewords) that were to be written to the secondary storage unit. Another example is, in the case of replacing a secondary storage unit, rebuilding any portions of encoded data payloads corresponding to the on the replacement secondary storage unit using the remaining portions of encoded data payloads on the other secondary storage units to recover the appropriate data payload and corresponding encoded portion of the data payload. Another example, in the case of a secondary storage unit needing data upkeep, is having the secondary storage unit self-report a need for garbage collection or consolidation of data. Alternatively, the data storage system could determine a secondary storage unit needs to undergo garbage collection or some other form of upkeep itself. Some embodiments may also chain multiple types of servicing into one “session” of servicing for efficiency reasons.

Some embodiments may differ in how and when a secondary storage unit is brought offline. For example, some embodiments may bring a secondary storage unit offline immediately, or near immediately, after determining the secondary storage unit needs servicing. Alternatively, some embodiments may delay when a secondary storage unit is brought offline. For example, some embodiments may use a set delay before bringing a secondary storage unit offline. Alternatively, some embodiments may take use a variable delay before bringing a secondary storage unit offline, which, as an example, could be based on current or historical characteristics and metrics of the data storage system. For example, some embodiments may choose to schedule servicing for downtime of a system, such as at nighttime.

Additionally, some embodiments, when bringing multiple secondary storage units offline, may bring all secondary storage units offline at once, may bring them offline sequentially or in sequential subgroups, or may use some other timing pattern, perhaps depending on other factors, to control the timing and order of bringing the secondary storage units offline for servicing. Some embodiments may also do additional tasks before performing servicing, such as shifting data, e.g., frequently accessed data, to a different secondary storage unit or performing other operations to increase the efficiency (e.g., reducing the required time) of the servicing task.

Some embodiments may handle the actual process of servicing a secondary storage unit in different ways. For example, in some embodiments the process of servicing a secondary storage unit may be handled by the secondary storage unit itself, e.g., when the secondary storage unit performs an automatic firmware update or autonomously handles firmware update after given the updated firmware to use. Alternatively, in some embodiments, the servicing of a secondary storage unit may be handled directly by the data storage system itself, such as the data storage system rebuilding any portions of encoded data payloads (e.g., codewords) corresponding to the on a new secondary storage unit that has replaced a previous secondary storage unit. Also, in some embodiments the servicing of a secondary storage unit may be handled by an outside agent that is neither the data storage system nor a secondary storage unit, such as by a human being (e.g., a human physically replacing a defective secondary storage unit). In some embodiments servicing a secondary storage unit may involve more than one agent acting. For example, some embodiments may involve the data storage system determining that a secondary storage unit is defective and needing replacement but have the data storage system send a request to a human operator who physically removes the defective secondary storage unit and inserts a new secondary storage unit. Additionally, in some embodiments, the servicing may be handled by different agents depending on the type of servicing being done.

Some embodiments may repair a secondary storage unit that was selected to receive a portion of an encoded data payload while the secondary storage unit was unavailable. Some embodiments may repair a secondary storage unit (with respect to some portion of a data payload) in response to the secondary storage unit being marked as needing to be repaired. Conversely, some embodiments may use different mechanisms to determine that a secondary storage unit needs repairing. In any case, to repair a secondary storage unit, some embodiments may recover the other portion of the encoded data payload that were written to other secondary storage units. The recovered portions of the encoded data payload may then be decoded into the original data payload. The original data payload may then be re-encoded to obtain the full encoded data payload. The portion of the encoded data payload meant for the secondary storage unit being repaired may then be written to the secondary storage unit. Some embodiments may then remove the indication that the secondary storage unit needs to be repaired with respect to the data payload. Some embodiments may then proceed to repair the secondary storage unit with respect to other data payloads, with repairing other secondary storage units, or with upgrading other secondary storage units.

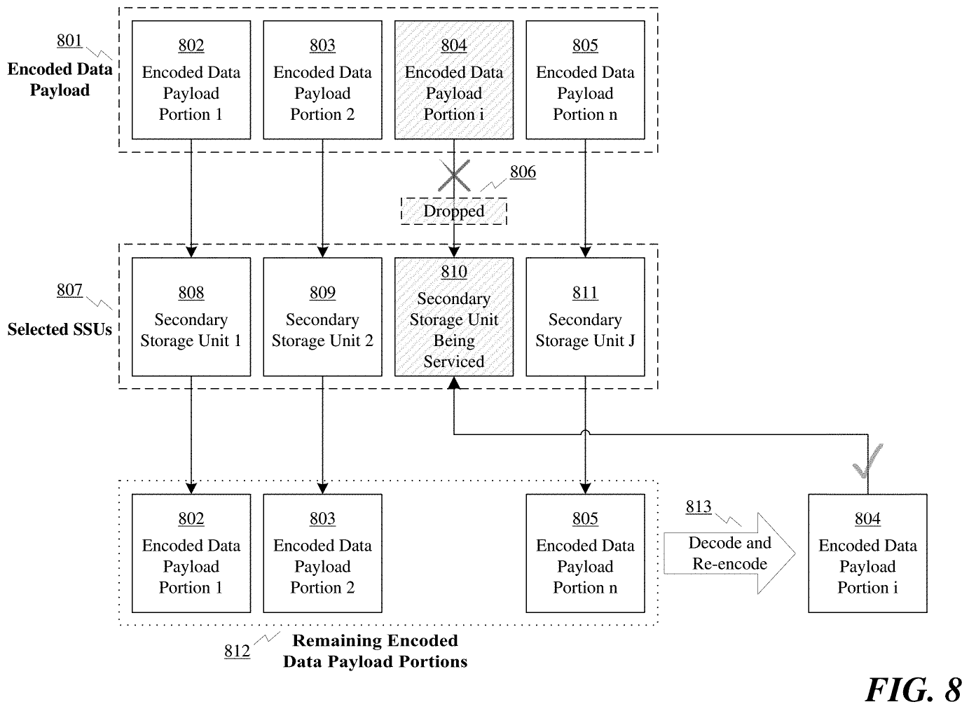

FIG. 8 is a schematic diagram providing an exemplary illustration of how a secondary storage unit may be repaired with respect to a portion of an encoded data payload the secondary storage unit missed. According to FIG. 8, encoded data payload 801 is composed of multiple encoded data payload portions, shown here as encoded data payload portions 802, 803, 804, and 805. Each encoded data payload portion is then written to one of the selected secondary storage units (SSUs) 807. If one of the selected secondary storage units 807, shown here as secondary storage unit 810, is offline for servicing, the encoded data payload portion 804 intended for the secondary storage unit may simply be dropped. In that case, secondary storage unit 810 may have a flag 806 recorded indicating that the secondary storage unit 810 needs to be repaired with respect to encoded data payload portion 804. To repair secondary storage unit 810, after secondary storage unit 810's has been serviced and the secondary storage unit is back online, the remaining encoded data payload portions 812 (shown here as encoded data payload portions 802, 803, and 804) are read from their respective secondary storage units (shown here as secondary storage units 808, 809, and 810). The remaining encoded data payload portions 812 are then decoded into the original data payload 813, which is then re-encoded into the encoded data payload 801. The dropped encoded data payload portion 804 is then written to secondary storage unit 810.

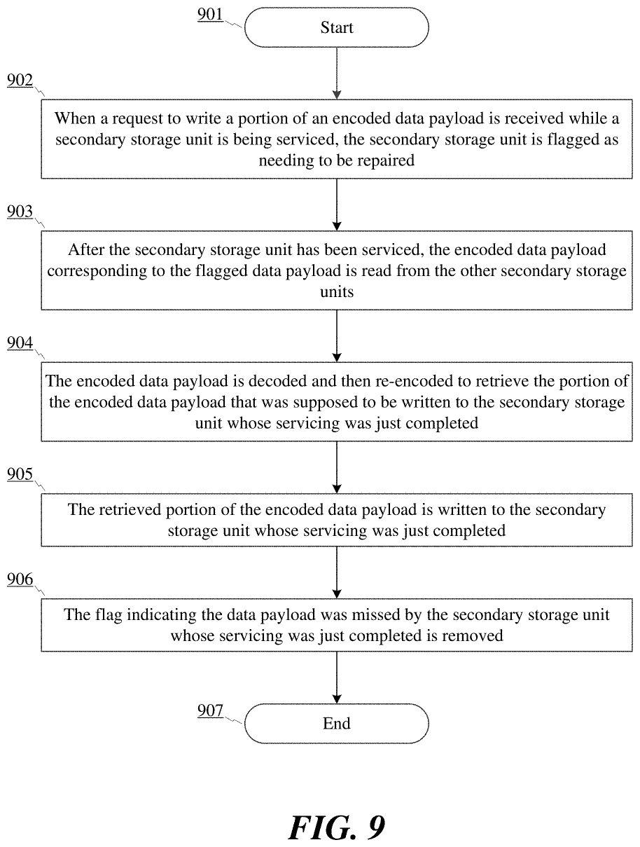

FIG. 9 is a flowchart outlining an exemplary method of repairing a secondary storage unit with respect to a portion of an encoded data payload the secondary storage unit missed. The method may be performed by a data storage system (e.g., data storage system 502 of FIG. 5 or data storage system 602 of FIG. 6).

As show by FIG. 9, in the first step 902, if a secondary storage unit (e.g., secondary storage unit 810 of FIG. 8) that is being serviced receives a request to write a portion of an encoded data payload (e.g., encoded data payload portion 804 of FIG. 8 which is part of encoded data payload 801 of FIG. 8), the secondary storage unit is flagged as having missed the portion of the encoded data payload the secondary storage unit was requested to write and needing to be repaired (with respect to the missed portion of the encoded data payload and/or the corresponding decoded data payload). Then, in step 903, after the secondary storage unit (e.g., secondary storage unit 810 of FIG. 8) has been serviced, the encoded data payload portions (corresponding to the encoded data payload missed by the now serviced secondary storage unit) that were successfully written to the remaining secondary storage units (e.g., the secondary storage units which successfully received and stored their respective encoded data payload portions, such as encoded data payload portions 802, 803, 804, and 805 of FIG. 8 which are stored on secondary storage units 808, 809, and 811 of FIG. 8, respectively) are read from the other secondary storage units (e.g., the selected SSUs 807 of FIG. 8 besides secondary storage unit 810).

In step 904, these encoded data payload portions (e.g., encoded data payload portions 802, 803, 804, and 805 of FIG. 8) are decoded into the original data payload and then re-encoded to reobtain the encoded data payload (e.g., encoded data payload 801 of FIG. 8). From the reobtained encoded data payload (e.g., encoded data payload 801 of FIG. 8), the encoded data payload portion that the now serviced secondary storage unit missed (e.g., encoded data payload portion 804 of FIG. 8) may be retrieved. Next, in step 905 the encoded data payload portion (e.g., encoded data payload portion 804 of FIG. 8) missed by the now serviced secondary storage unit (and which was just retrieved) (e.g., secondary storage unit 810 of FIG. 8) is written to the now serviced secondary storage unit. Finally, in step 906 the flag indicating the now serviced secondary storage unit (e.g., secondary storage unit 810 of FIG. 8) needs to be repaired with respect to this data payload is removed (the now serviced secondary storage unit may need to be repaired with respect to other data payloads, however).

Some embodiments may, before encoding a data payload, segment the data payload into multiple sub-payloads. Some embodiments may determine how many sub-payloads the data payload is split into based on various characteristics and information about the data storage system. Some embodiments may also consider the characteristics of the secondary storage units coupled to the data storage system, such as the overall number of secondary storage units coupled (e.g., connected) to the data storage system. The embodiments could also take into account characteristics of the secondary storage units themselves, such as the type of secondary storage units (e.g., HDD vs. SSD), current or historical I/O utilization of the secondary storage units, performance characteristics such the speed of the secondary storage units, or capacity utilization of the secondary storage units.

Some embodiments may also take into account characteristics of the data payload, such as if the data payload is frequently written to, frequently read from, and the nature of the writes and reads from the data payload, particularly by trying to concentrate characteristics true of only a part of the payload with one another in the sub-payloads. For example, some embodiments may attempt to concentrate data that is frequently read but not written to into a sub-payload, enabling the data storage system to more effectively store and handle the sub-payload without the frequent writes to other sub-payload interfering with read requests to the sub-payload. Furthermore, some embodiments may split the parcel of data into evenly sized sub-parcels of data. Conversely, some embodiments may split the sub-parcels into unequally sized sub-parcels of data. Splitting the sub-parcels into unequally sized sub-parcels of data may involve taking into account the various characteristics of the data, the characteristics of the data storage system itself, the characteristics of the coupled secondary storage units, or whether the data payload can be split in such a way as to maximize the concentration of data with given read and write patterns into their own respective sub-parcels.

In some embodiments, a non-transitory computer-readable storage medium including instructions is also provided, and the instructions may be executed by a device (such as the disclosed encoder and decoder), for performing the above-described methods. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same. The device may include one or more processors (CPUs), an input/output interface, a network interface, and/or a memory.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

It is appreciated that the above described embodiments can be implemented by hardware, or software (program codes), or a combination of hardware and software. If implemented by software, it may be stored in the above-described computer-readable media. The software, when executed by the processor can perform the disclosed methods. The data storage system, secondary storage unit, other functional units described in this disclosure can be implemented by hardware, or software, or a combination of hardware and software. One of ordinary skill in the art will also understand that multiple ones of the above described functional units may be combined as one functional unit, and each of the above described functional units may be further divided into a plurality of functional sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A method of operating a data storage system, the method comprising:
receiving an I/O request to write a payload of data;
encoding the payload of data, wherein the encoded data payload comprises a plurality of encoded data payload portions;
selecting two or more secondary storage units from a plurality of secondary storage units coupled to the data storage system, wherein:
the plurality of secondary storage units includes a first secondary storage unit that is being serviced,
the first secondary storage unit, while being serviced, is not excluded from being selected as one of the two or more secondary storage units, and
each of the encoded data payload portions are assigned to corresponding secondary storage units from the two or more secondary storage units; and
sending the plurality of encoded data payload portions to the two or more selected secondary storage units for storage, wherein each encoded data payload portion is sent to the corresponding assigned secondary storage unit from the two or more selected secondary storage units.

2. The method of claim 1, wherein encoding the payload of data comprises encoding the payload of data using erasure coding.

3. The method of claim 1, wherein selecting two or more secondary storage units from the plurality of secondary storage units is based on:
current or historical I/O utilization of the plurality of secondary storage units,
current or historical I/O queue of the plurality of secondary storage units,
current or historical capacity utilization of the plurality of secondary storage units,
performance characteristics of the plurality of secondary storage units, or
characteristics of the payload of data.

4. The method of claim 1, wherein servicing the first secondary storage unit comprises:
upgrading the firmware of the first secondary storage unit,
rebuilding encoded data payload portions assigned to the first secondary storage unit that have become corrupted,
replacing the first secondary storage unit with a different secondary storage unit,
optimizing the storage of the encoded data payload portions on the first secondary storage unit's physical blocks, or
performing garbage collection on the first secondary storage unit's physical blocks.

5. The method of claim 1, further comprising:
determining that the first secondary storage unit has a servicing operation to be performed; and
responsive to determining that the first secondary storage unit has a servicing operation to be performed, initiating servicing of the first secondary storage unit.

6. The method of claim 5, wherein determining that the first secondary storage unit has a servicing operation to be performed is based on determining that:
a firmware upgrade is available for the first secondary storage unit,
encoded data payload portions assigned to the first secondary storage unit have become corrupted,
the first secondary storage unit has failed,
the first secondary storage unit is close to failure,
the encoded data payload portions are suboptimally stored on the first secondary storage unit's physical blocks, or
the first secondary storage unit has physical blocks that have not undergone garbage collection after storing data that was invalidated.

7. The method of claim 1, further comprising marking for rebuilding any secondary storage unit of the two or more selected secondary storage units that did not successfully store one or more of the assigned encoded data payload portions sent to the secondary storage unit for storage, wherein the mark for rebuilding is with respect to the one or more assigned encoded data payload portions.

8. The method of claim 7, wherein:
the first secondary storage unit is one of the two or more selected secondary storage units;
the first secondary storage unit did not successfully store one or more corresponding assigned encoded data payload portions; and
the first secondary storage unit is marked for rebuilding.

9. The method of claim 8, further comprising rebuilding data on the first secondary storage unit, after the first secondary storage unit has been serviced, with respect to the one or more assigned encoded data payload portions that were not successfully stored.

10. The method of claim 7, further comprising rebuilding data on any secondary storage unit marked for rebuilding.

11. The method of claim 10, wherein rebuilding data on any secondary storage unit comprises:
obtaining, from the two or more selected secondary storage units that are not marked for rebuilding, a threshold amount of the encoded data payload portions;
responsive to obtaining the threshold amount of the encoded data payload portions:
decoding the threshold amount of the encoded data payload portions into the payload of data;
reencoding the payload of data into to reobtain the encoded data payload, wherein:
the reobtained encoded data payload comprises the plurality of encoded data payload portions, and
the plurality of encoded data payload portions includes the assigned encoded data payload portions that were not successfully stored by the secondary storage unit being rebuilt; and
sending the assigned encoded data payload portions that were previously unsuccessfully stored to the secondary storage unit being rebuilt for storage.

12. The method of claim 11, further comprising, responsive to data on the secondary storage unit being rebuilt successfully, removing the mark for rebuilding from the secondary storage unit.

13. A non-transitory computer readable medium that stores a set of instructions that is executable by at least one processor of a data storage system to cause the data storage system to perform a method of operating, the method comprising:
receiving an I/O request to write a payload of data;
encoding the payload of data, wherein the encoded data payload comprises a plurality of encoded data payload portions;
selecting two or more secondary storage units from a plurality of secondary storage units coupled to the data storage system, wherein:
the plurality of secondary storage units includes a first secondary storage unit that is being serviced,
the first secondary storage unit, while being serviced, is not excluded from being selected as one of the two or more secondary storage units, and
each of the encoded data payload portions are assigned to corresponding secondary storage units from the two or more secondary storage units; and
sending the plurality of encoded data payload portions to the two or more selected secondary storage units for storage, wherein each encoded data payload portion is sent to the corresponding assigned secondary storage unit from the two or more selected secondary storage units.

14. The non-transitory computer readable medium of claim 13, wherein encoding the payload of data comprises encoding the payload of data using erasure coding.

15. The non-transitory computer readable medium of claim 13, wherein the set of instructions is executable by the at least one processor of the data storage system to cause the data storage system to further perform:
determining that the first secondary storage unit has a servicing operation to be performed; and
responsive to determining that the first secondary storage unit has a servicing operation to be performed, initiating servicing of the first secondary storage unit.

16. The non-transitory computer readable medium of claim 13, wherein the set of instructions is executable by the at least one processor of the data storage system to cause the data storage system to further perform marking for rebuilding any secondary storage unit of the two or more selected secondary storage units that did not successfully store one or more of the assigned encoded data payload portions sent to the secondary storage unit for storage, wherein the mark for rebuilding is with respect to the one or more assigned encoded data payload portions.

17. The non-transitory computer readable medium of claim 13, wherein:
the first secondary storage unit is one of the two or more selected secondary storage units;
the first secondary storage unit did not successfully store one or more corresponding assigned encoded data payload portions; and
the first secondary storage unit is marked for rebuilding.

18. The non-transitory computer readable medium of claim 16, wherein the set of instructions is executable by the at least one processor of the data storage system to cause the data storage system to further perform rebuilding data on the first secondary storage unit, after the first secondary storage unit has been serviced, with respect to the one or more assigned encoded data payload portions that were not successfully stored.

19. The non-transitory computer readable medium of claim 18, wherein rebuilding data on the first secondary storage unit comprises:
obtaining, from the two or more selected secondary storage units that are not marked for rebuilding, a threshold amount of the encoded data payload portions;
responsive to obtaining the threshold amount of the encoded data payload portions:
decoding the threshold amount of the encoded data payload portions into the payload of data;
reencoding the payload of data into to reobtain the encoded data payload, wherein:
the reobtained encoded data payload comprises the plurality of encoded data payload portions, and
the plurality of encoded data payload portions includes the assigned encoded data payload portions that were not successfully stored by the first secondary storage unit; and
sending the assigned encoded data payload portions that were previously unsuccessfully stored to the first secondary storage unit for storage.

20. A data storage system, comprising:
a plurality of secondary storage units;
an I/O interface; and
one or more processors communicatively coupled to the plurality of secondary storage units and I/O interface, wherein the one or more processors are configured to:
receive, from the I/O interface, a request to write a payload of data;
encode the payload of data, wherein the encoded data payload comprises a plurality of encoded data payload portions;
select two or more secondary storage units from the plurality of secondary storage units, wherein:
the plurality of secondary storage units includes a first secondary storage unit that is being serviced,
the first secondary storage unit, while being serviced, is not excluded from being selected as one of the two or more secondary storage units, and
the first secondary storage unit, while being serviced, is not excluded from being selected as one of the two or more secondary storage units, and
each of the encoded data payload portions are assigned to corresponding secondary storage units from the two or more secondary storage units; and
sending the plurality of encoded data payload portions to the two or more selected secondary storage units for storage, wherein each encoded data payload portion is sent to the corresponding assigned secondary storage unit from the two or more selected secondary storage units.

21. The data storage system of claim 20, wherein encoding the payload of data comprises encoding the payload of data using erasure coding.

22. The data storage system of claim 20, wherein the one or more processors are further configured to:
determine that the first secondary storage unit has a servicing operation to be performed; and
responsive to determining that the first secondary storage unit has a servicing operation to be performed, initiate servicing of the first secondary storage unit.

23. The data storage system of claim 20, wherein the one or more processors are further configured to mark for rebuilding any secondary storage unit of the two or more selected secondary storage units that did not successfully store one or more of the assigned encoded data payload portions sent to the secondary storage unit for storage, wherein the mark for rebuilding is with respect to the one or more assigned encoded data payload portions.

24. The data storage system of claim 20, wherein:
the first secondary storage unit is one of the two or more selected secondary storage units;
the first secondary storage unit did not successfully store one or more corresponding assigned encoded data payload portions; and
the first secondary storage unit is marked for rebuilding.

25. The data storage system of claim 23, wherein the one or more processors are further configured to rebuild data on the first secondary storage unit, after the first secondary storage unit has been serviced, with respect to the one or more assigned encoded data payload portions that were not successfully stored.

26. The data storage system of claim 25, wherein rebuilding data on the first secondary storage unit comprises:
obtaining, from the two or more selected secondary storage units that are not marked for rebuilding, a threshold amount of the encoded data payload portions;
responsive to obtaining the threshold amount of the encoded data payload portions:
decoding the threshold amount of the encoded data payload portions into the payload of data;
reencoding the payload of data into to reobtain the encoded data payload, wherein:
the reobtained encoded data payload comprises the plurality of encoded data payload portions, and
the plurality of encoded data payload portions includes the assigned encoded data payload portions that were not successfully stored by the first secondary storage unit; and
sending the assigned encoded data payload portions that were previously unsuccessfully stored to the first secondary storage unit for storage.

27. A data storage system, comprising:
a memory storing a set of instructions; and
one or more processors configured to execute the set of instructions to cause the data storage system to perform:
receiving an I/O request to write a payload of data;
encoding the payload of data, wherein the encoded data payload comprises a plurality of encoded data payload portions;
selecting two or more secondary storage units from a plurality of secondary storage units coupled to the data storage system, wherein:
the plurality of secondary storage units includes a first secondary storage unit that is being serviced,
the first secondary storage unit, while being serviced, is not excluded from being selected as one of the two or more secondary storage units, and
each of the encoded data payload portions are assigned to corresponding secondary storage units from the two or more secondary storage units; and
sending the plurality of encoded data payload portions to the two or more selected secondary storage units for storage, wherein each encoded data payload portion is sent to the corresponding assigned secondary storage unit from the two or more selected secondary storage units.

28. A method of operating a data storage system, the method comprising:
receiving an I/O request to read a payload of data corresponding to an encoded data payload, wherein the encoded data payload comprises a plurality of encoded data payload portions;
obtaining, from a plurality of secondary storage units coupled to the data storage system, a threshold amount of the encoded data payload portions, wherein:
the encoded data payload is stored on two or more secondary storage units from the plurality of secondary storage units,
each of the encoded data payload portions is stored on corresponding assigned secondary storage units from the two or more secondary storage units, and
the two or more secondary storage units includes a first secondary storage unit that is being serviced; and
responsive to obtaining the threshold amount of the encoded data payload portions, decoding the threshold amount of the encoded data payload portions into the payload of data.
